(19) United States
(12) Patent Application Publication
(10) Pub. No.: US 2018/0073145 A1
(43) Pub. Date: Mar. 15, 2018

(54) AUXILIARY DEVICE FOR PLASMA-ENHANCED CHEMICAL VAPOR DEPOSITION (PECVD) REACTION CHAMBER AND FILM DEPOSITION METHOD USING THE SAME

(71) Applicant: Yu-Shun CHANG, Taipei City (TW)

(72) Inventor: Yu-Shun CHANG, Taipei City (TW)

(21) Appl. No.: 15/413,923

(22) Filed: Jan. 24, 2017

(30) Foreign Application Priority Data
Sep. 9, 2016 (TW) 105129308

(51) Int. Cl. C23C 16/505; C23C 16/52; H01J 37/32

(52) U.S. Cl. CPC C23C 16/505; C23C 16/52; H01J 2237/3321; H01J 37/32669; H01J 37/32357; H01J 37/3211

(57) ABSTRACT

An auxiliary device for a plasma-enhanced chemical vapor deposition (PECVD) reaction chamber and a film deposition method using the same are revealed. The auxiliary device includes a first electric field device set around an inner wall of the reaction chamber. Thus source materials or film precursors in the plasma are moved from a center toward the inner wall around the reaction chamber by electrical attraction of the first electric field device. The auxiliary device further includes a second electric field device set under a platform surface loaded with a substrate. The second electric field device makes source materials or film precursors in the plasma become attached to and deposited on a surface of the substrate owing to electrical attraction. Thereby uniformity of the film can be controlled effectively and thickness of the film can be reduced.

### BACKGROUND OF THE INVENTION

The present invention relates to an auxiliary device for a chemical vapor deposition (CVD) reaction chamber and a film deposition method using the same, especially to an auxiliary device for a plasma-enhanced chemical vapor deposition (PECVD) reaction chamber and a film deposition method using the same.

Chemical vapor deposition (CVD) is a technique for depositing a thin film of materials on surface of substrates. Source materials (also called film precursors, reaction sources) in gas form (called main gas) are introduced into a reaction chamber to carry out chemical reactions such as oxidation, reduction on a substrate surface. Then the product is deposited on the substrate surface to form the thin film by internal diffusion. The manufacturing process of the CVD in the reactor chamber includes the following steps. (1) Gas sources (or main gas) are introduced into a reaction chamber. (2) The sources diffuse to pass through the boundary layer and contact with a substrate surface. (3) The sources are attached to the substrate surface. (4) The attached sources move on the substrate surface. (5) Chemical reactions occur on the substrate surface. (6) Solid by-products form crystal nuclei on the substrate surface. (7) The crystal nuclei grow into islands. (8) The islands congregate to form a continuous film. (9) Other gas by-products are released from the substrate surface. (10) The gas by-products diffuse through the boundary layer. (11) The gas by-products escape from the reaction chamber.

PECVD (Plasma-enhanced CVD) is a specific type of CVD. PECVD has a wide variety of applications, being used to form thin film of oxide and nitride. PECVD is similar to CVD. The plasma includes chemically active ions and radicals and the substrate surface hit by ions also has higher chemical activity. Thus the chemical reaction rate of the substrate surface is accelerated. Therefore the main advantage of PECVD over CVD is that the deposition can occur at lower temperature. Moreover, there is a remote plasma-enhanced CVD (RPECVD) in which the substrate is not directly in the plasma discharge region. A plasma generator is arranged separately from a reaction chamber and is called a remote plasma generator. Gaseous source materials are introduced into the plasma generator first to generate plasma by microwave or radiofrequency power. Then the plasma is introduced into the reaction chamber.

There is a plurality of related prior arts in the field of CVD, PECVD, and remote PECVD including U.S. Pat. No. 5,908,602, U.S. Pat. No. 6,444,945, US App. No. 2006/0177599, U.S. provisional App. No. 61/137,839 (TWI532414), and so on. Most of the conventional PECVD devices are used in small-scale deposition (smaller than m²) because that the plasma sources are only suitable for small area coating. Refer to U.S. Pat. No. 6,444,945, a plasma source includes a structure made up of two hollow cathode shapes connected to a bipolar AC power supply is revealed. Yet more energy is consumed so that the production cost is increased. Refer to US. Pat. App. No. 61/137,839, it provides novel linear and two dimensional plasma sources that produce linear and two dimensional plasmas, respectively, that are useful for plasma-enhanced chemical vapor deposition.

Moreover, users usually have a plurality of requirements for the films produced by CVD or PECVD such as good step coverage, high aspect ratio, high thickness uniformity, high purity and density, etc. As to PECVD for preparing films, one of the shortcomings thereof is insufficient uniformity of source materials or film precursors in plasma of the reaction chamber before being deposited on the substrate surface. Thus the film formed on the substrate surface has poor uniformity. Another disadvantage is that source materials or film precursors are freely deposited on the substrate surface after nucleation. Thus the film formed on the substrate surface has a certain thickness, unable to be minimized. Therefore one more abrasion process is required for planarization and uniformity of the film before performing the following thin film deposition processes of PECVD.

Thus there is room for improvement and there is a need to provide a novel PECVD technique that produces films with better uniformity and a smaller thickness.

### SUMMARY OF THE INVENTION

Therefore it is a primary object of the present invention to provide an auxiliary device for a plasma-enhanced chemical vapor deposition (PECVD) reaction chamber in which a film produced is more homogeneous, the efficiency of the PECVD reaction chamber in use is improved and the process efficiency is increased.

In order to achieve the above object, an auxiliary device for a plasma-enhanced chemical vapor deposition (PECVD) reaction chamber according to the present invention is provided. At least one electric field device is disposed on a PECVD reaction chamber. The electric field device is arranged around an inner wall of the reaction chamber and used to provide electrical attraction to plasma in the reaction chamber. Thus source materials or film precursors in the plasma are moved from a center of the reaction chamber toward the inner wall around the reaction chamber before being attached and deposited on the surface of the substrate to form the film.

It is another object of the present invention to provide an auxiliary device for a plasma-enhanced chemical vapor deposition (PECVD) reaction chamber by which thickness of the film deposited can be controlled and minimized effectively. The trouble of abrasion and further processing of the thicker film produced by conventional techniques can be avoided and the process efficiency of the PECVD reaction chamber is improved.

In order to achieve the above object, an auxiliary device for a plasma-enhanced chemical vapor deposition (PECVD) reaction chamber according to the present invention is provided. At least one electric field device is disposed on a PECVD reaction chamber. The electric field device is arranged under a platform surface of the reaction chamber and used to provide electrical attraction to plasma in the reaction chamber.

The platform surface is used for loading a substrate. Thus source materials or film precursors in the plasma are attached to and deposited on a surface of the substrate owing to effect of the electrical attraction.

It is a further object of the present invention to provide an auxiliary device for a plasma-enhanced chemical vapor deposition (PECVD) reaction chamber in which a radiofrequency (RF) magnetic field device is mounted in a PECVD reaction chamber and used for control of an angle of epitaxy deposited on a surface of the substrate.

In order to achieve the above object, an auxiliary device for a plasma-enhanced chemical vapor deposition (PECVD) reaction chamber according to the present invention includes a RF magnetic field device arranged under a center of a platform surface of the reaction chamber. The platform surface is used for loading a substrate.

It is a further object of the present invention to provide a film deposition method using plasma-enhanced chemical vapor deposition (PECVD) that includes the following steps. Step (a): introducing plasma formed by source materials or film precursors into a PECVD reaction chamber while the reaction chamber is disposed with a platform surface used for loading at least one substrate. Step (b): providing a first electric field device that is disposed around an inner wall of the reaction chamber for improving uniformity of a film deposited by using the first electric field device to provide electrical attraction to the plasma in the reaction chamber so that the source materials or the film precursors in the plasma are diffused and moved from a center of the reaction chamber toward the inner wall around the reaction chamber before being attached and deposited on a surface of the substrate to form the film.

It is a further object of the present invention to provide a film deposition method using plasma-enhanced chemical vapor deposition (PECVD) that further includes a step (c) after the step (b): providing a second electric field device that is arranged at a surface of the platform surface opposite to the surface of the platform surface of the reaction chamber with the substrate, and used for providing electrical attraction to the plasma in the reaction chamber so that the sources materials or the film precursors in the plasma are attached and deposited on the surface of the substrate owing to the electrical attraction.

It is a further object of the present invention to provide a film deposition method using plasma-enhanced chemical vapor deposition (PECVD) that further includes a step (d) after the step (c): providing a radiofrequency (RF) magnetic field device that is arranged under a center of the platform surface of the reaction chamber and used for control of an angle of epitaxy deposited on the surface of the substrate.

### BRIEF DESCRIPTION OF THE DRAWINGS

FIG. 1 is a longitudinal sectional view of an embodiment of an auxiliary device for a plasma-enhanced chemical vapor deposition (PECVD) reaction chamber according to the present invention;

FIG. 2 is a longitudinal sectional view of another embodiment of an auxiliary device for a plasma-enhanced chemical vapor deposition (PECVD) reaction chamber according to the present invention.

### DETAILED DESCRIPTION OF THE PREFERRED EMBODIMENTS

In order to learn features and functions of the present invention, please refer to the following embodiments with the related figures. Each component in the figures is not drawn to scale.

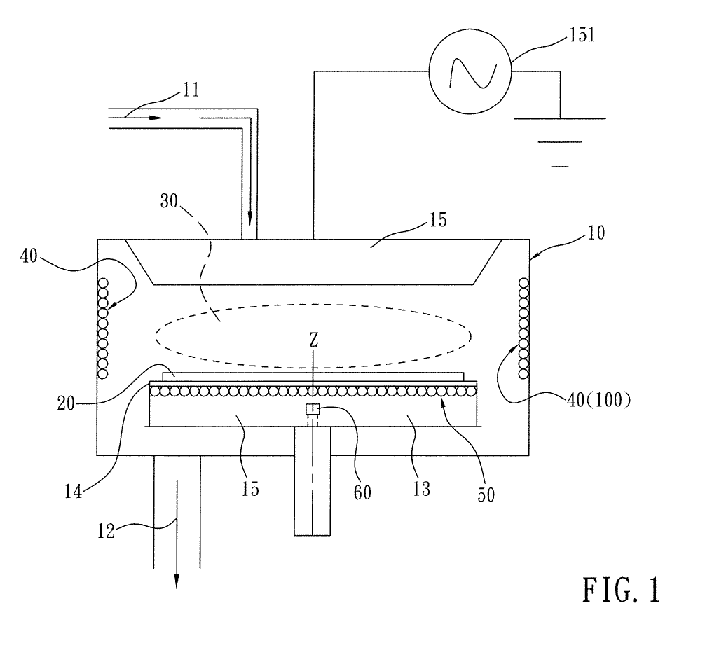

Refer to FIG. 1, a reaction chamber 10 of this embodiment can be, but not limited to a reaction chamber of a common plasma-enhanced chemical vapor deposition (PECVD). The reaction chamber 10 includes a process gas inlet 11, a by-product outlet 12, a platform 13, a platform surface 14 and two parallel electrode plates 15. The process gas includes source materials (also called reaction sources or film precursors) in gas form. The gas by-products are drawn out of the reaction chamber 10 through the by-product outlet 12 by a vacuum pump. The platform 13 is used for heating while the platform surface 14 is set on the platform 13 and used for loading at least one substrate 20. By the electrode plates 15 and a radio frequency generator 151, radio frequency is applied to the process gas to form plasma 30 in the reaction chamber 10. The plasma 30 is generated by ionization of the process gas when energy applied is larger than dissociation energy of the process gas. The energy applied can be high-voltage direct current, radio frequency, microwave, etc. Most of the energy applied is transferred to electrons and then electrons got energy collide with other particles. Nearly no energy is transferred during electric collision between electron and larger particles. After getting sufficient energy, electrons are excited and dissociated by inelastic collisions with heavier neutral particles. The plasma is maintained by constant collisions between electrons and heavier particles. Thus plasma is a partially ionized gas formed by positive charges (ions), negative charges (electrons) and neural radicals. The above components 11, 12, 13, 14, 15, and 151 of the reaction chamber 10 can be produced by technique available now. Thus the details of structure and functions of the respective component are not described here.

The present invention features on that an auxiliary device for the reaction chamber 10 of the present invention includes at least one electric field device. The electric field device is a first electric field device 40 disposed around an inner wall of the reaction chamber 10. An electric field is generated by the first electric field device 40 that uses radiofrequency (RF) current flowing through a coil. Then the electric field formed provides electrical attraction to the plasma 30 in the reaction chamber 10 so that source materials or film precursors in the plasma 30 are diffused and moved from a center of the reaction chamber 10 (as the Z axis indicates in FIG. 1) toward the inner wall around the reaction chamber 10 before being attached and deposited on at least one surface of the substrate 20 to form the film. Thus the film formed is more even and homogeneous.

Moreover, the first electric field device 40 uses RF current passed through a coil to generate an electric field. The RF used can be varied according to density of the source material. For example, the RF can be, but not limited to, 700 v/m±6%, 1300 v/m±6%, or 1900 v/m±6%.

Another feature of the present invention is that the auxiliary device for the reaction chamber 10 further includes a second electric field device 50 arranged under the platform surface 14 of the reaction chamber 10. The second electric field device 50 also generates an electric field by using RF current flowing through a spiral coil (wound around the Z axis as shown in FIG. 1). The electric field formed by the second electric field device 50 also provides electrical attraction to the plasma 30 in the reaction chamber 10 so that the source material or the film precursor in the plasma 30 is attached and deposited on at least one surface of the substrate 20 by the electrical attraction. While in use, the electric field effect of the first electric field device 40 is off first and then the electric field effect of the second electric field device 50 is on. That means the first electric field device 40 and the second electric field device 50 are arranged and operated separately. After the second electric field device 50 being turned on, the plasma 30 in the reaction chamber 10 is under electrical attraction of the electric field formed and source materials or film precursors in the plasma 30 is forced to be attached to or deposited on at least one surface of the substrate 20 faster. Thus the thickness of the film deposited can be controlled and reduced effectively.

The second electric field device 50 generates an electric field by using RF current passed through a spiral coil wound around the Z axis. The RF used varies according to concentration of the source material in gas form. For example, the RF can be, but not limited to, 90 uv/m±4.5%, 500 uv/m±4.5%, or 1100 uv/m±4.5%.

A further feature of the present invention is in that the auxiliary device for the reaction chamber 10 further includes a radiofrequency (RF) magnetic field device 60 that is arranged under a center (as the Z axis in FIG. 1 indicates) of the platform surface 14 of the reaction chamber 10 and used for control of an angle of epitaxy deposited on the surface of the substrate 20.

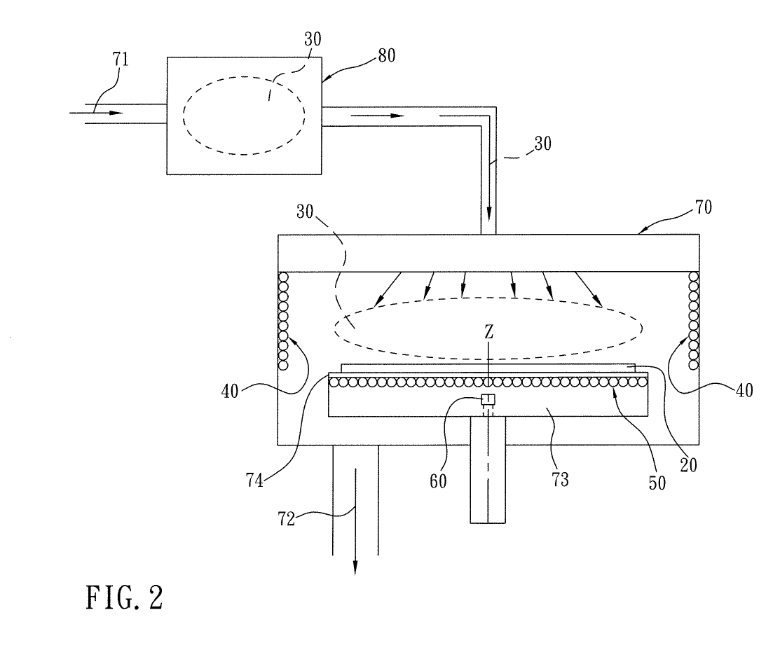

Refer FIG. 2, a sectional view of another embodiment is revealed. A reaction chamber 70 can be, but not limited to, a reaction chamber of a conventional remote PECVD. The reaction chamber 70 consists of a process gas inlet 71, a remote plasma generation chamber 80, a by-product outlet 72, a platform 73, and a platform surface 74. The process gas includes source materials (also called reaction sources, film precursors) in gas form. In this embodiment, the remote plasma generation chamber 80 uses, but not limited to, high-voltage direct current (DC), radiofrequency (RF), microwave, etc to provide external energy to the process gas for generating plasma 30 in the remote plasma generation chamber 80. Then the plasma 30 is introduced into the reaction chamber 70. The gas by-products are drawn out of the reaction chamber 70 through the by-product outlet 72 by a vacuum pump. The platform 73 is used to heat while the platform surface 74 is set on the platform 73 and used for loading at least one substrate 20. The difference between this embodiment and the above one is in that plasma is produced by the process gas in the remote plasma generation chamber 80 first and then is introduced into the reaction chamber 70 in this embodiment while the plasma 30 is formed in the reaction chamber 10 by the electrode plates 15 and the radio frequency generator 151 that applies radio frequency in the above embodiment. Moreover, the above components 70, 71, 72, 73 and 74 can all be produced by the technique available now. The detailed structure and functions of these components are not described here.

The embodiment in FIG. 2 features on a first electric field device 40, a second electric field 50 and a RF magnetic field device 60, the same as the above embodiment in FIG. 1.

A film deposition method using plasma-enhanced chemical vapor deposition (PECVD) according to the present invention includes the following steps.

Step (a): introducing plasma 30 formed by source materials or film precursors into a PECVD reaction chamber 10/or 70 while the reaction chamber 10/or 70 is disposed with a platform surface 14/or 74 used for loading at least one substrate 20.

Step (b): providing a first electric field device 40 that is disposed around an inner wall of the reaction chamber 10/or 70, as shown in FIG. 1 and FIG. 2 for improving uniformity of a film deposited. The first electric field device 40 is used to provide electrical attraction to the plasma 30 in the reaction chamber 10/or 70 so that the source materials or the film precursors in the plasma 30 are diffused and moved from a center of the reaction chamber 10/or 70 (as the Z axis indicates in FIG. 1) toward the inner wall around the reaction chamber 10/or 70 before being attached and deposited on the surface of the substrate 20 to form the film. Thus the film formed is more even and homogeneous.

After the step (b), the film deposition method of the present invention further includes a step (c): providing a second electric field device 50 that is arranged at a surface of the platform surface 14/or 74 of the reaction chamber 10/or 70, opposite to the surface of the platform surface 14/or 74 of the reaction chamber 10/or 70 with the substrate 20, and used for providing electrical attraction to the plasma 30 in the reaction chamber 10/or 70 so that the sources materials or the film precursors in the plasma are attached and deposited on the surface of the substrate 20 owing to the electrical attraction.

After the step (b), the film deposition method of the present invention further includes a step (c): providing a RF magnetic field device 60 that is arranged under a center of the platform surface 14/or 74 of the reaction chamber 10/or 70 and used for control of an angle of epitaxy deposited on the surface of the substrate 20.

Additional advantages and modifications will readily occur to those skilled in the art. Therefore, the invention in its broader aspects is not limited to the specific details, and representative devices shown and described herein. Accordingly, various modifications may be made without departing from the spirit or scope of the general inventive concept as defined by the appended claims and their equivalent.

What is claimed is:

1. An auxiliary device for a plasma-enhanced chemical vapor deposition (PECVD) reaction chamber comprising:
at least one electric field device;
wherein the electric field device is disposed in the reaction chamber and used for generating at least one electric field to electrically attract plasma in the PECVD reaction chamber;
wherein the PECVD reaction chamber includes a process gas inlet for introducing process gas containing source materials in gas form, a by-product outlet through which gas by-products are drawn out of the reaction chamber, a platform, and a platform surface set on the platform and used for loading at least one substrate; wherein the plasma in the PECVD reaction chamber is formed by the process gas.

2. The device as claimed in claim 1, wherein the plasma in the PECVD reaction chamber is formed by the process gas and produced in the PECVD reaction chamber or in a remote plasma generator.

3. The device as claimed in claim 1, wherein the electric field device is a first electric field arranged around an inner wall of the PECVD reaction chamber; an electric field generated by the first electric field device provides electrical attraction to the plasma in the PECVD reaction chamber so that the source materials in the plasma are diffused and moved from a center of the PECVD reaction chamber to the inner wall around the PECVD reaction chamber before being attached and deposited on at least one surface of the substrate to form the film; thus uniformity of the film is improved.

4. The device as claimed in claim 3, wherein the first electric field device generates the electric field by using radiofrequency (RF) current passed through a coil; the RF used varies according to density of the source material.

5. The device as claimed in claim 4, wherein the RF is selected from the group consisting of 700 v/m±6%, 1300 v/m±6%, and 1900 v/m±6%.

6. The device as claimed in claim 1, wherein the electric field device is a second electric field disposed under the platform surface of the PECVD reaction chamber; the electric field formed by the second electric field device provides electrical attraction to the plasma in the PECVD reaction chamber so that the source materials in the plasma is attached and deposited on at least one surface of the substrate by the electrical attraction for control of thickness of a film deposited.

7. The device as claimed in claim 6, wherein the second electric field device generates the electric field by using radiofrequency (RF) current flowing through a spiral coil; the RF used varies according concentration of the source material in gas form.

8. The device as claimed in claim 7, wherein the RF is selected from the group consisting of 90 uv/m±4.5%, 500 uv/m±4.5%, and 1100 uv/m 4.5%.

9. The device as claimed in claim 1, wherein the auxiliary device for the PECVD reaction chamber further includes a radiofrequency (RF) magnetic field device set under a center of the platform surface of the PECVD reaction chamber and used for control of an angle of epitaxy deposited on at least one surface of the substrate.

10. A film deposition method using plasma-enhanced chemical vapor deposition (PECVD) comprising the steps of:
(a): introducing plasma formed by source materials into a PECVD reaction chamber while the PECVD reaction chamber is disposed with a platform surface used for loading at least one substrate; and
(b): providing a first electric field device disposed around an inner wall of the PECVD reaction chamber for improving uniformity of a film deposited by using the first electric field device to provide electrical attraction to the plasma in the PECVD reaction chamber so that the source materials in the plasma are moved from a center of the PECVD reaction chamber toward the inner wall around the PECVD reaction chamber before being attached to and deposited on a surface of the substrate to form the film.

11. The method as claimed in claim 10, wherein after the step (b), the film deposition method using PECVD further includes a step (c) of providing a second electric field device that is arranged at a surface of the platform surface opposite to the surface of the platform surface with the substrate, and used for providing electrical attraction to the plasma in the PECVD reaction chamber so that the sources materials in the plasma are attached and deposited on the surface of the substrate owing to the electrical attraction.

12. The method as claimed in claim 10, wherein after the step (c), the film deposition method using PECVD further includes a step (d) of providing a radiofrequency (RF) magnetic field device that is arranged under a center of the platform surface of the PECVD reaction chamber for control of an angle of epitaxy deposited on the surface of the substrate.
